(19) United States
(12) Patent Application Publication
(10) Pub. No.: US 2025/0183123 A1
(43) Pub. Date: Jun. 5, 2025

(54) POWER MODULE HAVING INTERCONNECTED BASE PLATE WITH MOLDED METAL AND METHOD OF MAKING THE SAME

(71) Applicant: ALPHA AND OMEGA SEMICONDUCTOR INTERNATIONAL LP, TORONTO (CA)

(72) Inventors: Zhiqiang Niu, Santa Clara, CA (US); Bum-Seok Suh, SEONGNAM-CITY (KR); Long-Ching Wang, Cupertino, CA (US); Son Tran, San Jose, CA (US); Junho Lee, Yeongtong-gu Suwon-si (KR); Yueh-Se Ho, Sunnyvale, CA (US)

(73) Assignee: ALPHA AND OMEGA SEMICONDUCTOR INTERNATIONAL LP, TORONTO, ON (CA)

(21) Appl. No.: 19/035,694

(22) Filed: Jan. 23, 2025

Related U.S. Application Data
(62) Division of application No. 16/705,898, filed on Dec. 6, 2019.

(51) Int. Cl. H01L 23/492; H01L 21/56; H01L 21/768; H01L 21/78; H01L 23/053; H01L 23/14; H01L 23/16; H01L 23/28

(52) U.S. Cl. CPC H01L 23/492; H01L 21/563; H01L 21/565; H01L 21/768; H01L 21/78; H01L 23/053; H01L 23/142; H01L 23/16; H01L 23/28

(57) ABSTRACT

An interconnected base plate comprises a metal layer, a plurality of metal pads, and a molding encapsulation. The mold compound layer encloses a majority portion of the plurality of metal pads 240. A respective top surface of each of the plurality of metal pads is exposed from a top surface of the molding encapsulation. The respective top surface of said each of the first plurality of metal pads and the top surface of the mold compound layer are co-planar. A power module comprises the interconnected base plate, a plurality of chips, a plurality of bonding wires, a plurality of terminals, a plastic case, and a module-level molding encapsulation. A method, for fabricating an interconnected base plate, comprises the steps of forming a plurality of metal pads; loading a metal layer; forming a molding encapsulation; and applying a singulation process.

### CROSS-REFERENCE TO RELATED APPLICATIONS

This Patent Application is a Divisional Application of a pending application Ser. No. 16/705,898 filed on Dec. 6, 2019. The entire Disclosure made in the pending application Ser. No. 16/705,898 is hereby incorporated by reference.

### FIELD OF THE INVENTION

This invention relates generally to an interconnected base plate with molded metal and a method of making the same. More particularly, the present invention relates to a power module comprising the interconnected base plate with molded metal.

### BACKGROUND OF THE INVENTION

FIG. 1A shows a top view and FIG. 1B shows a cross sectional view along AA′ of a conventional power module 100 comprising a plurality of insulated metal base plates 120. The plurality of insulated metal base plates 120 comprise a first plate 120A, a second plate 120B, and a third plate 120C. The first plate 120A, the second plate 120B, and the third plate 120C are of rectangular shapes so as not to extend to the surrounding boundary regions 160, 162, 164, and 166. The first plate 120A is separated from the second plate 120B by a first gap 140A. The second plate 120B is separated from the third plate 120C by a second gap 140B. A plurality of chips 133 are mounted on a bottom metal layer 137. FIG. 1C shows a cross sectional view of another conventional power module 101. A bottom metal layer 172 is separated from a top metal layer 174 by an insulation layer 190. The top metal layer 174 is of a rectangular shape not extending to the surrounding boundary regions 161 and 165.

One application for the present disclosure is for a power invert module, comprising an interconnected base plate, with electrical current in a range from 25 amperes to 200 amperes; with voltage of 600 volts or 1,200 volts; and with the dimension of 107 mm×45 mm×17 mm or 122 mm×62 mm×17 mm. The electrical traces and the electrical pads are embedded in the molding encapsulation. With pre-determined percentage of the fillers and the type of the fillers, the coefficient of thermal expansion (CTE) of the mold compound layer is adjusted to be close to the CTE of a copper material. Therefore, the thermal stress developed in the interconnected base plate is reduced. The power invert module has a high power capability and a high thermal cycling capability (from −40 degrees Centigrade to 125 Centigrade for thousands of cycles). The chip mounting area is increased by 23%. The trace inductance is reduced. The manufacturing cost is reduced.

### SUMMARY OF THE INVENTION

The present invention discloses an interconnected base plate comprising a metal layer, a plurality of metal pads, and a molding encapsulation. The mold compound layer encloses a majority portion of the plurality of metal pads. A respective top surface of each of the plurality of metal pads is exposed from a top surface of the molding encapsulation. The respective top surface of said each of the first plurality of metal pads and the top surface of the mold compound layer are co-planar. A power module comprises the interconnected base plate, a plurality of chips, a plurality of bonding wires, a plurality of terminals, a plastic case, and a module-level molding encapsulation.

A method for fabricating an interconnected base plate is also disclosed. The method comprises the steps of forming a plurality of metal pads; loading a metal layer; forming a molding encapsulation; and applying a singulation process.

### BRIEF DESCRIPTION OF THE DRAWINGS

FIG. 1A is a top view and FIG. 1B is a cross sectional view of a conventional power module. FIG. 1C is a cross sectional view of another conventional power module.

FIG. 2A is a top view and FIG. 2B is a perspective view of a power module in examples of the present disclosure.

FIG. 3 is a cross sectional view along BB′ of the power module of FIG. 2A in examples of the present disclosure.

FIG. 4 is a cross sectional view of another power module in examples of the present disclosure.

FIG. 5 is a flowchart of a process to develop an interconnected base plate in examples of the present disclosure.

FIGS. 6A, 6B, 6C, 6D, 6E, 6F, 6G, 6H, 6I and 6J show the steps of the process to fabricate an interconnected base plate in examples of the present disclosure.

FIG. 7 is a flowchart of a process to develop a power module in examples of the present disclosure.

### DETAILED DESCRIPTION OF THE INVENTION

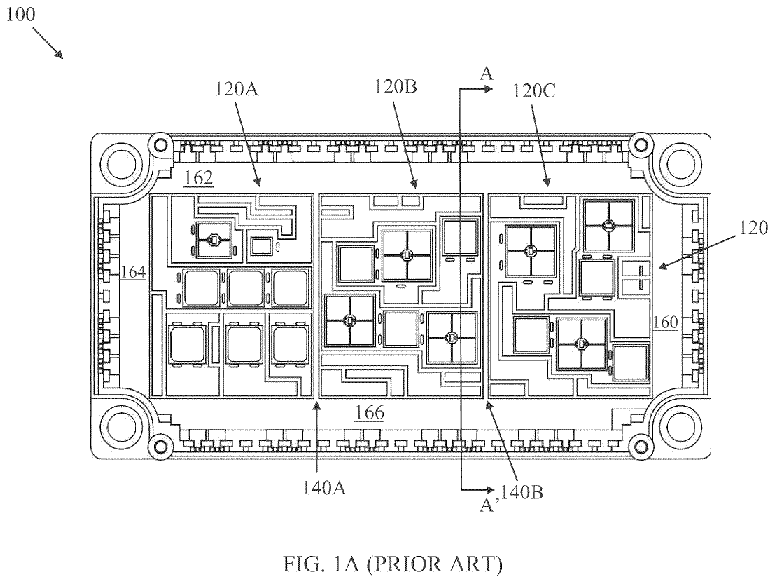

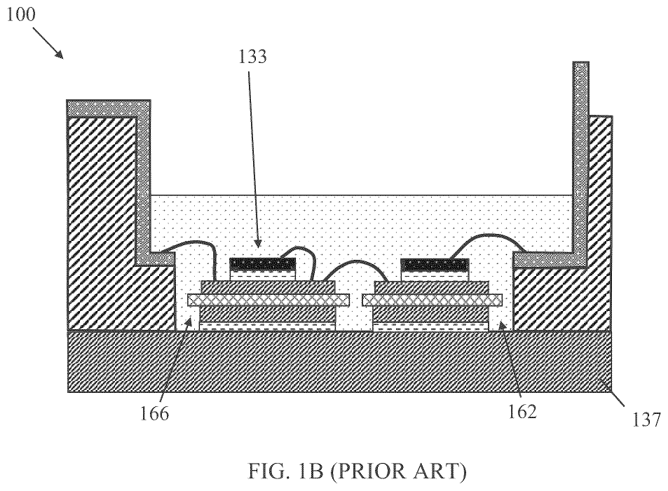

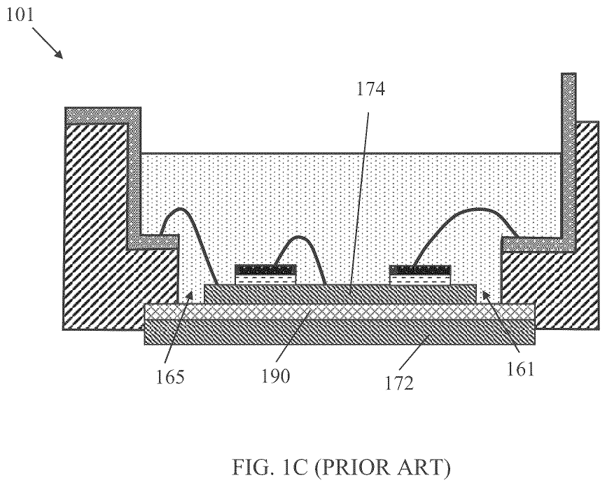

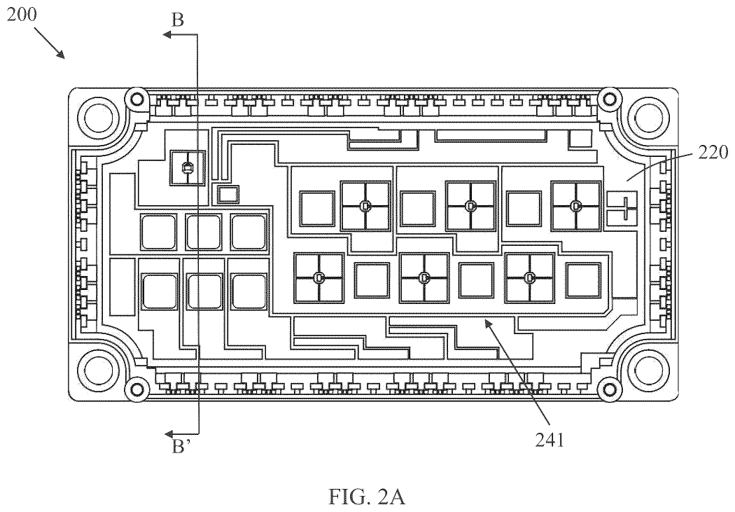

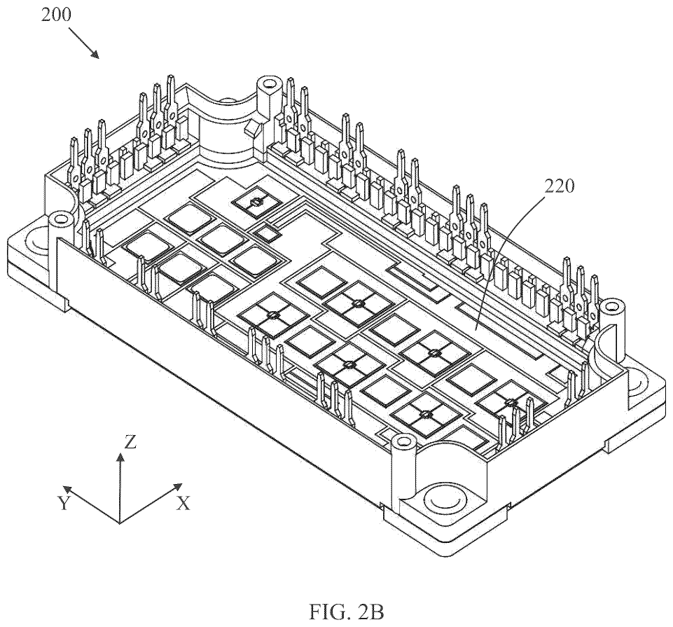

FIG. 2A is a top view and FIG. 2B is a perspective view of a power module 200 in examples of the present disclosure. The power module 200 comprises an interconnected base plate 220. The interconnected base plate 220 is not limited to a rectangular shape as the plurality of insulated metal base plates 120 of the conventional power module 100 of FIG. 1A. The interconnected base plate 220 is not required to be separated by the first gap 140A and the second gap 140B as shown in FIG. 1A. The interconnected base plate 220 can extend to the boundary regions 160, 162, 164, and 166 as shown in FIG. 1A.

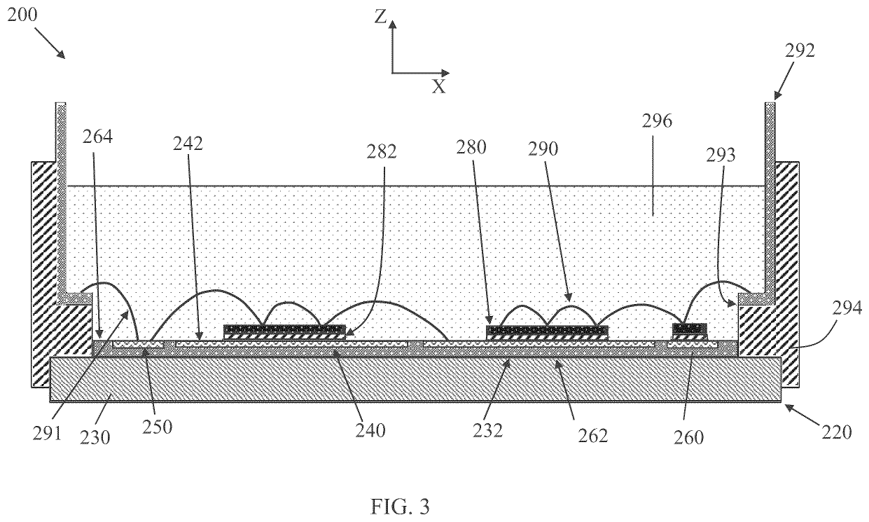

FIG. 3 is a cross sectional view along BB′ of the power module 200 of FIG. 2A in examples of the present disclosure. The power module 200 comprises an interconnected base plate 220, a plurality of chips 280, a first plurality of bonding wires 290, a second plurality of bonding wires 291, a plurality of terminals 292, a plastic case 294, and a module-level molding encapsulation 296. In examples of the present disclosure, the module-level molding encapsulation 296 is formed in a different molding process from the molding process forming the mold compound layer 260. As shown, the plastic case 294 comprises a plurality of sidewalls disposed on a periphery of the interconnected base plate.

The interconnected base plate 220 comprises a bottom metal plate 230 extending through the entire interconnected base plate 220, a plurality of metal traces 241, a first plurality of metal pads 240 in a central area, and a second plurality of metal pads 250 in edge areas embedded in a mold compound layer 260 overlaying the metal layer 230. In examples of the present disclosure, the bottom metal plate 230 is of a rectangular prism shape. The mold compound layer 260 is of a rectangular prism shape. The second plurality of metal pads 250 are electrically connected to plurality of terminals 292. The mold compound layer 260 encloses a majority portion of the first plurality of metal pads 240 and a majority portion of the plurality of metal traces 241. The mold compound layer 260 encloses a majority portion of the second plurality of metal pads 250. An entire bottom surface 262 of the mold compound layer 260 is directly attached to a top surface 232 of the metal layer 230. The mold compound layer covers an entire central area of the bottom metal plate and extends to reach sidewalls of the plastic case 294. Edges of the mold compound layer 260 are substantially aligned to the interior sidewalls of the plastic case 294 to provide the benefit of self-fit-in while assembling the plastic case 294 to the interconnected base plate 220. A respective top surface 242 of each of the first plurality of metal pads 240 is exposed from a top surface 264 of the mold compound layer 260. The respective top surface 242 of said each of the first plurality of metal pads 240 and the top surface 264 of the mold compound layer 260 are co-planar. The metal traces 241, the first plurality of metal pads 240 and the second plurality of metal pads 250 preferably have a same thickness between 100 to 800 microns, with a minimum space of 400 microns between adjacent metal pads or traces filed with the mold compound layer 260. A thickness of mold compound layer 260 below the metal traces 241, the first plurality of metal pads 240 and the second plurality of metal pads 250 is preferably between 100 to 500 microns to provide insulation from the bottom metal plate 230. A length (along X-direction) of the mold compound layer 260 is shorter than a length (along X-direction) of the metal layer 230. A width (along Y-direction) of the mold compound layer 260 is shorter than a width (along Y-direction) of the metal layer 230.

Each of the plurality of chips 280 is attached to a respective metal pad of the first plurality of metal pads 240 by a respective conductive material of a plurality of conductive materials 282. In one example, the plurality of conductive materials 282 are solder pastes. In another example, the plurality of conductive materials 282 are conductive adhesives. The module-level molding encapsulation 296 encloses the plurality of chips 280, the first plurality of bonding wires 290, the second plurality of bonding wires 291, a portion of the plurality of terminals 292, and an interior portion of the plastic case 294. A bottom surface 293 of each of the plurality of terminals 292 is directly attached to the plastic case 294. The top surface 264 of the mold compound layer 260 is directly attached to the plastic case 294.

In examples of the present disclosure, the bottom metal plate 230 is made of a first copper material. The first plurality of metal pads 240 and the second plurality of metal pads 250 are made of a second copper material. In one example, the first copper material and the second copper material are the same copper material. In another example, the first copper material and the second copper material are different copper alloys.

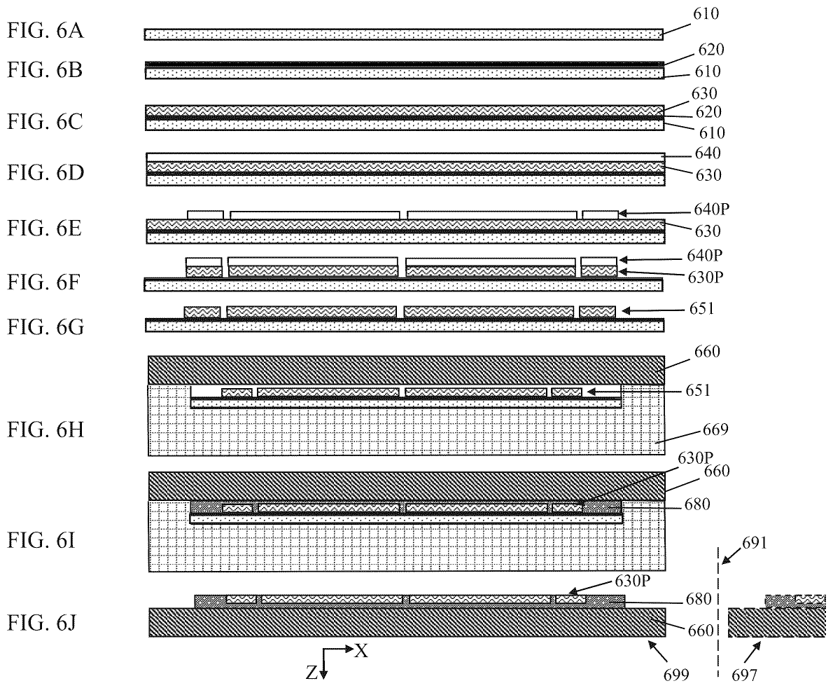

In examples of the present disclosure, the mold compound layer 260 is of a single-piece construction that is formed in a single molding process as shown in FIG. 6I. In examples of the present disclosure, the mold compound layer 260 is made of a resin or a gel.

In examples of the present disclosure, the mold compound layer 260 is made of a resin containing one or more filler materials selected from the group consisting of silicon oxide (SiO2), aluminum oxide (Al2O3), and aluminum nitride (AlN). In examples of the present disclosure, a percentage of filling of the one or more filler materials is in a range from eighty percent to ninety percent. In a first example, the mold compound layer 260 contains 80% silicon oxide fillers. In a second example, the mold compound layer 260 contains 85% aluminum oxide fillers. In a third example, the mold compound layer 260 contains 90% aluminum nitride fillers. In a fourth example, the mold compound layer 260 contains 20% silicon oxide fillers, 30% aluminum oxide fillers, and 40% aluminum nitride fillers. In examples of the present disclosure, the percentage of the fillers and the type of the fillers are determined to adjust the coefficient of thermal expansion (CTE) of the mold compound layer 260. In one example, the CTE of mold compound layer 260 with fillers is in a range from 99% to 101% of the CTE of the metal layer 230. In another example, the CTE of mold compound layer 260 with fillers is in a range from 97% to 103% of the CTE of the metal layer 230. In still another example, the CTE of mold compound layer 260 with fillers is in a range from 95% to 105% of the CTE of the metal layer 230.

In examples of the present disclosure, a thickness of each of the first plurality of metal pads 240 is less than a thickness of the mold compound layer 260. A thickness of each of the second plurality of metal pads 250 is less than the thickness of the mold compound layer 260.

In examples of the present disclosure, a thickness of the bottom metal plate 230 is in a range from five hundred microns (0.5 mm) to eight hundred microns (0.8 mm).

In examples of the present disclosure, a thermal conductivity of the mold compound layer 260 is in a range from 5 watt per meter kelvin to 10 watt per meter kelvin.

In examples of the present disclosure, the second plurality of metal pads 250 are electrically connected to the plurality of terminals 292 by the second plurality of bonding wires 291.

FIG. 4 is a cross sectional view of a power module 400 in examples of the present disclosure. The power module 400 comprises an interconnected base plate 220, a plurality of chips 280, a first plurality of bonding wires 290, a plurality of conductive plates 491, a plurality of terminals 292, a plastic case 294, and a module-level molding encapsulation 296.

The interconnected base plate 220 comprises a metal layer 230, a first plurality of metal pads 240, a second plurality of metal pads 250, and a mold compound layer 260. In examples of the present disclosure, the bottom metal plate 230 is of a rectangular prism shape. The mold compound layer 260 is of a rectangular prism shape. The second plurality of metal pads 250 are electrically connected to plurality of terminals 292. The mold compound layer 260 encloses a majority portion of the first plurality of metal pads 240. A bottom surface 262 of the mold compound layer 260 is parallel and is directly attached to a top surface 232 of the metal layer 230. A respective top surface 242 of each of the first plurality of metal pads 240 is exposed from a top surface 264 of the mold compound layer 260. The respective top surface 242 of said each of the first plurality of metal pads 240 and the top surface 264 of the mold compound layer 260 are co-planar. A length (along X-direction) of the mold compound layer 260 is shorter than a length (along X-direction) of the metal layer 230. A width (along Y-direction) of the mold compound layer 260 is shorter than a width (along Y-direction) of the metal layer 230.

In examples of the present disclosure, the second plurality of metal pads 250 are electrically connected to the plurality of terminals 292 by a plurality of conductive plates 491. In one example, each of the second plurality of metal pads 250, a respective conductive plate of the plurality of conductive plates 491, and a respective terminal of the plurality of terminals 292 are of a single-piece construction (made in a same metal forming process). In another example, each of the second plurality of metal pads 250, a respective conductive plate of the plurality of conductive plates 491, and a respective terminal of the plurality of terminals 292 are of a three-piece construction (made in three separated metal forming processes and then attached to one another).

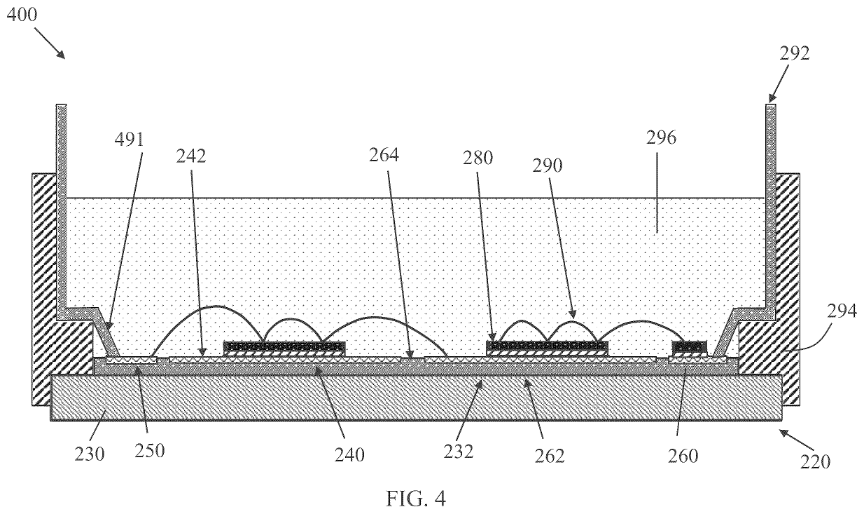

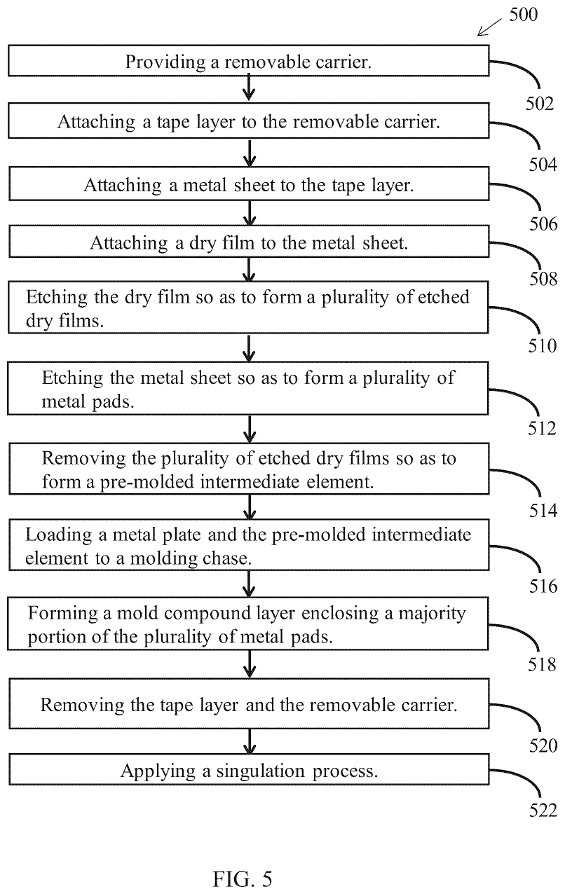

FIG. 5 is a flowchart of a process 500 to develop an interconnected base plate in examples of the present disclosure. In one example, the interconnected base plate is developed from a panel. The panel is of a rectangular shape. Several hundreds or several thousands of the interconnected base plates are made from a single panel. The process 500 may start from block 502. FIGS. 6A-6J show the cross sections of the corresponding steps. For simplicity, only one interconnected base plate is shown in the panel in FIGS. 6A-6I. The right one in dashed lines of FIG. 6J (same structure as the corresponding left one in solid lines) is not shown in FIGS. 6A-6I.

In block 502, referring now to FIG. 6A, a removable carrier 610 is provided. In one example, the removable carrier 610 is of a rectangular prism shape. Block 502 may be followed by block 504.

In block 504, referring now to FIG. 6B, a tape layer 620 is attached to the removable carrier 610. In examples of the present disclosure, the tape layer 620 is a double-sided tape. The tape layer 620 is pressed onto the removable carrier. Block 504 may be followed by block 506.

In block 506, referring now to FIG. 6C, a metal sheet 630 is attached to the tape layer 620. In examples of the present disclosure, the metal sheet 630 is made of a copper material. Block 506 may be followed by block 508.

In block 508, referring now to FIG. 6D, a dry film 640 is attached to the metal sheet 630. Block 508 may be followed by block 510.

In block 510, referring now to FIG. 6E, the dry film 640 of FIG. 6D is etched so as to form a plurality of etched dry films 640P. Block 510 may be followed by block 512.

In block 512, referring now to FIG. 6F, the metal sheet 630 of FIG. 6E is etched so as to form a plurality of metal pads 630P. Block 512 may be followed by block 514.

In block 514, referring now to FIG. 6G, the plurality of etched dry films 640P are removed so as to form a pre-molded intermediate element 651. Block 514 may be followed by block 516.

In block 516, referring now to FIG. 6H, a metal plate 660 and the pre-molded intermediate element 651 are loaded to a molding chase 669. The metal pads 630P face the metal plate 660 with a preset space between 100 to 800 microns separating the metal pads 630P from the metal plate 660. Block 516 may be followed by block 518.

In block 518, referring now to FIG. 6I, a molded interconnected base plate assembly is formed by injecting mold compound layer 680 to fill the spaces between the metal plate 660, the metal pads 630P and the tape layer 620. The mold compound layer 680 encloses a majority portion of the plurality of metal pads 630P. The mold compound layer 680 is directly attached to the metal layer 660. Block 518 may be followed by block 520.

In block 520, referring now to FIG. 6J, the tape layer 620, and the removable carrier 610 are removed after the molded interconnected base plate assembly is removed from the molding chase 669,. The viewing direction in Z-direction is flipped (the mold compound layer 680 is below the metal layer 660 in FIG. 6I and the mold compound layer 680 is above the metal layer 660 in FIG. 6J). Block 520 may be followed by block 522.

In block 522, a singulation process 691 separates the interconnected base plate 699 of FIG. 6J from adjacent interconnected base plate 697 shown in dashed lines. Alternatively, this singulation process may be carried out after semiconductor chips are mounted on the entire panel of the interconnected base plates and/or plastic cases are mounted onto the panel of the interconnected base plates.

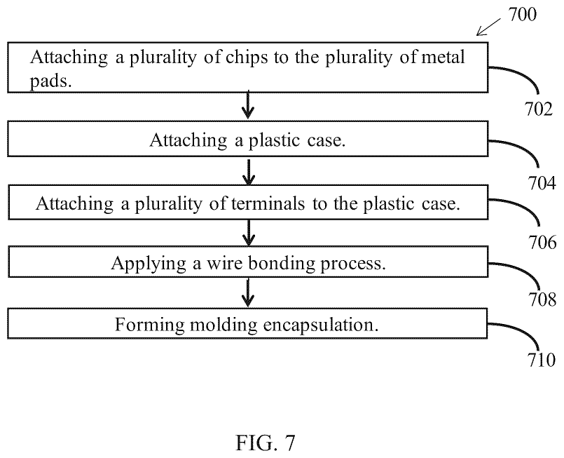

FIG. 7 is a flowchart of a process 700 to develop a power module in examples of the present disclosure. In one example, the process 700 is conducted before the step of applying a singulation process of block 522 of FIG. 5. The process 700 may start from block 702.

In block 702, a plurality of chips 280 of FIG. 3 are attached to the plurality of metal pads 630P of FIG. 6J. Block 702 may be followed by block 704.

In block 704, a plastic case 294 of FIG. 3 is attached to the metal plate 660 of FIG. 6J. Block 704 may be followed by block 706.

In block 706, a plurality of terminals 292 of FIG. 3 are attached to the plastic case 294 of FIG. 3. Block 706 may be followed by block 708.

In block 708, a first plurality of bonding wires 290 of FIG. 3 are bonded to the plurality of chips 280 of FIG. 3. Block 708 may be followed by block 710.

In block 710, a module-level molding encapsulation 296 of FIG. 3 is formed. The module-level molding encapsulation 296 of FIG. 3 encloses the plurality of chips 280 of FIG. 3, the first plurality of bonding wires 290 of FIG. 3, a portion of the plurality of terminals 292 of FIG. 3, and a portion of the plastic case 492 of FIG. 3.

Those of ordinary skill in the art may recognize that modifications of the embodiments disclosed herein are possible. For example, a number of the plurality of terminals 292 may vary. Other modifications may occur to those of ordinary skill in this art, and all such modifications are deemed to fall within the purview of the present invention, as defined by the claims.

1. A method for fabricating an interconnected base plate, the method comprising the steps of:
providing a removable carrier;
attaching a tape layer to the removable carrier;
attaching a metal sheet to the tape layer;
attaching a dry film to the metal sheet;
etching the dry film so as to form a plurality of etched dry films;
etching the metal sheet so as to form a plurality of metal pads;
removing the plurality of etched dry films so as to form a pre-molded intermediate element;
loading a metal plate and the pre-molded intermediate element to a molding chase, the metal pads facing the metal plate with a preset space therebetween;
forming a molded interconnected base plate assembly by injecting a mold compound layer filling space between the metal plate, the plurality of metal pads and the tape layer, the mold compound layer enclosing a majority portion of the plurality of metal pads; and
removing the tape layer, and the removable carrier after the molded interconnected base plate assembly removed from the molding chase.

2. The method of claim 1 further comprising a step of applying a singulation process separating the interconnected base plate from adjacent interconnected base plate after removing the tape layer and the removable carrier.

3. The method of claim 1, wherein the metal plate is made of a first copper material;
wherein the mold compound layer is made of a resin; and
wherein the plurality of metal pads are made of a second copper material.

4. The method of claim 1, wherein the mold compound layer is made of a resin containing one or more filler materials selected from the group consisting of silicon oxide, aluminum oxide, and aluminum nitride; and
wherein a percentage of filling of the one or more filler materials is in a range from eighty percent to ninety percent.

5. The method of claim 1, wherein a thickness of each of the plurality of metal pads is less than a thickness of the mold compound layer.

6. The method of claim 1, wherein a thickness of the metal plate is in a range from five hundred microns to eight hundred microns.

7. The method of claim 1, wherein a thermal conductivity of the mold compound layer is in a range from five watt per meter kelvin to ten watt per meter kelvin.

8. The method of claim 1, after the step of removing the tape layer and the removable carrier,
a respective top surface of each of the plurality of metal pads is exposed from a top surface of the mold compound layer; and
wherein the respective top surface of said each of the plurality of metal pads and the top surface of the mold compound layer are co-planar.
